(19) United States
(12) Patent Application Publication
(10) Pub. No.: US 2008/0264474 A1
(43) Pub. Date: Oct. 30, 2008

(54) Solar System and Method for the Operation Thereof

(76) Inventors: Hana Frauenknecht, Kussnacht (CH); Rudolf Moll, Schwyz (CH); Sandor Palffy, Ennetbaden (CH)

Correspondence Address: SCHWEITZER CORNMAN GROSS & BONDELL LLP, 292 MADISON AVENUE - 19th FLOOR, NEW YORK, NY, 10017, US

(21) Appl. No.: 12/094,498

(22) PCT Filed: Nov. 27, 2006
(86) PCT No.: PCT/CH2006/000661

§ 371 Date: May 21, 2008

(30) Foreign Application Priority Data
Nov. 29, 2005 (EP) 05405676.7

(51) Int. Cl. H01L 31/048

(52) U.S. Cl. 136/251; 126/606

(57) ABSTRACT

Disclosed is a solar system comprising a solar panel (1) that is composed of spaced-apart modules (11-14) which are oriented in a North-South direction in an inclined position. The modules (11-14) are mounted on a support (15) which is in contact with an adaptively program-controlled electric drive (5). Said electric drive and thus the entire panel (1) are time-dependently swiveled about a stationary shaft (6) so as to obtain maximum solar radiation. The drive (5) is self-sufficiently powered by a solar module (11), thus dispensing with the need for solar sensors and auxiliary power supplies. An operating method aims to maximize solar output while taking into account the duration of daylight. The inventive system is used particularly for supplying emergency power to sensitive infrastructures. Several systems can be mechanically or electrically connected to each other according to the master-and-slave principle so as to create a solar park and be part of a large power system. The invention allows power to be produced and supplied in a very safe and economic manner.

The present invention relates to a solar plant according to the preamble of claim 1 and to a method of operating it according to claim 15.

It is generally known that with the tracking of solar panels in two axes it is possible to achieve an additional annual energy gain of up to 40 percent as compared with stationary panels arranged only in the north-south direction. In the case of panels arranged in the north-south direction with an elevation of from 20° to 40° and which can be pivoted by 60° out of the horizontal on both sides of the axis of elevation, an additional energy gain of approximately 30 percent can be anticipated.

A storm-proof, pivotable solar panel is known from U.S. Pat. No. 5,228,924. At least two modules are mounted in a tiltable manner on a fixed shaft between triangular supports, adjacent modules being coupled to one another mechanically. They are pivoted by a total of 130° from east to west by means of telescopic bars by a reversible electromechanical spindle drive situated inside the supports. The drive is controlled in accordance with a time-dependent program, either electromechanically or by a computer.

A drawback with this plant is the relatively high energy requirement for the drive and the control thereof, so that it is necessary to connect to the mains in order to supply it. On account of the drive and on kinematic grounds it is only possible for the plant to be provided with an axis of rotation arranged horizontally, so that the altitude of the sun (elevation) is not taken into consideration, which leads to a sharply reduced solar yield in particular in the winter months at locations north of the Tropic of Cancer and south of the Tropic of Capricorn respectively.

The model of a biaxial solar plant (JP 2002 061962 A) likewise dispenses with sensors customary elsewhere; the control means is supplied by the plant itself.

This is not a design suitable for all weathers: the exposed worm gears on each solar module for setting the azimuth position are extremely susceptible to breakdown. Even with the intended intermittent operation of the drive motors, the latter encumber the overall energy balance and during operation lead to a disproportionately high voltage drop in the solar modules, but enormous frictional losses occur as a result of the multiplicity of worm gears (illustrated: 22).

In general, solar panels rotatable on one and two axes have until now failed to become widespread in the generation of energy, being regarded as expensive and susceptible to breakdown.

The object of the invention is therefore to provide a solar plant which is reliable in operation and which with an economically justifiable outlay provides a considerably higher yield as compared with stationary solar plants. In particular, better use should be made of the daily duration of sunshine. In this way, the plant should deliver electrical energy even in the early morning hours and until sunset. In addition, in the case of diffuse radiation it has to be possible for a maximum yield corresponding to the solar modules to be achieved. The plant has to be constructed in a weatherproof manner, i.e. it should remain capable of operating for example at any temperatures which occur on a house roof and under extreme wind conditions (storms); it also has to withstand strong gusts and heavy snow loads without damage. Precautions must therefore be taken in the plant in order to reduce the forces acting upon the mechanical design in the case of a solar panel turned against the wind. Likewise in winter it is necessary to prevent the formation of a coherent covering of ice and/or snow on the surface of the solar panel.

The mechanical design of the plant should be sufficiently simple for it to be capable of being erected and operated with very simple means wherever building approval permits it. It should also be able to receive solar modules of existing stationary plants and to be used in their place. This also permits an ecologically and economically acceptable retrofitting of existing plants whilst retaining the entire electrical installation. After the retrofitting the average annual solar yield is increased by approximately 30%, but not the maximum power in the case of the highest position of the sun, so that the old inverted rectifiers can also remain unchanged.

This object is attained by the features of the Claims.

In accordance with claim 1 the energy for driving the displacement motor is taken off directly from a power cell (i.e. a solar module), as a result of which external supplies of any type can be omitted. In this way, energy for the intermittent tilting of all the modules on an axis rotation is available to an adequate extent at any time of day, without the power balance of the attached solar module being adversely affected to a significant degree.

Storage batteries, the electrical power of which—as is known—is dependent upon the temperature, are likewise not necessary. The pivoting movement is carried out as a result of the drive turning about the fixed gearwheel at intervals by a pre-set angle and jointly moving (“pivoting”) the support structure (“support”) of the solar module by way of its base plate. This movement pattern reduces the technical outlay and the current requirement to a considerable degree as compared with a continuous tracking.

In accordance with the method according to Claim 15, an optimum energy-saving actuation of a drive for solar plants is achieved. The energy consumption required for this is very low; it corresponds approximately to that of a momentary shading of a single module by a cloud passing by. The return of the panel into the morning starting position can be carried out by a motor or in an exclusively mechanical manner by way of a spring tensioned in the course of the day. With the control means characterized in the Claim, sensor cells and the like as well as corresponding regulating circuits are rendered unnecessary and the construction of plants operating in a trouble-free manner is made possible. Irrespective of the currently prevailing atmospheric conditions, an optimum amount of energy is always received by the solar modules. This applies even when the sky is overcast or when clouds are passing by, but the control means always knows where the sun is located. In this way, the panel is directed towards the maximum radiation even with diffuse radiation.

The discontinuous control in accordance with pre-set angle settings is particularly efficient. On account of the high degree of sensitivity to radiation and the relative lack of susceptibility to small changes in the angle, in modern solar modules no measurable loss of power occurs as compared with a continuous tracking of the sun.

Technical further developments of the subject of the invention, which optimize the latter, are described in further dependent Claims:

The formation of air gaps by resilient spacer elements between individual solar modules prevents an “aerofoil effect” in the event of incident flow against the panel (wind, gusts). Even a gap of more than 15 mm results in an adequate pressure equalization (relief) between the underside and the top side of the solar panel as a whole. In the case of snowfall a cohesive blanket of snow cannot form on the panel, again as a result of the gaps, so that the reduction in the electrical power on account of deposits of snow is smaller and/or is only of shorter duration as compared with mutually abutting solar modules.

The mounting of the solar modules on the wide side of a U-shaped profile allows the latter to be held in a simple and secure manner and at the same time provides space for fitting bearing supports which receive the rotating axle of the plant. As a result, it is additionally possible to use the area extending over the centre axis. This is in contrast to a drive with a tubular drive and cells resting centrally against it. Further advantages are a smaller polar mass moment of inertia as well as lower imbalances as a result of asymmetry.

In addition, it is recommended that the modules should be mounted laterally and thus centred in a smaller U-shaped profile, particularly in the case of relatively large modules.

A spring rod can move the non-braked solar panel automatically into its horizontal zero position. This simplifies the control procedure and increases the reliability of the system, and, as a result, the panel can still be brought into a rest position for the night in a very simple manner. In addition, this rest position can also be set up in the same way during the day before hurricane-like storms arise. A plurality of spring rods of different dimensions are also possible, which, arranged below the solar panel, result in an objectspecific spring characteristic.

The relatively high torque to be applied by the spring rod (“bending rod”) from the drive can be achieved without difficulty by an optimization of the drive (gearing ratio and rotational speed of the motor). The rod can be easily adapted to the drive control, so that it can be rotated pre-stressed, i.e. in the centre, so that the rest position of the panel is set in the direction tilted towards the east. This simplifies the control program on the one hand and already permits a gain in solar energy in the early morning on the other hand.

An arrangement with a leaf spring is preferred, which is guided on rollers at the front end on the panel and is capable of being set in its spring force centrally on the fixed shaft of the panel by rotation.

A hollow shaft as a support axle has the effect of reducing weight without a loss of stability occurring, which is of great importance particularly in the case of assembly on roofs. In the case of relatively long shafts, attached (shrunk-on) sliding bushings permit the use of inexpensive tubes and, in addition, prevent bending under load.

A torsion spring, which is mounted in the hollow shaft and which can follow a progressive spring characteristic either on its own or in conjunction with a spring rod, has also been produced.

The power transmission of the drive by means of a segment of a toothed rim, which is preferably arranged in the region of the upper end of the axis of rotation, is particularly simple and easy to service. In accordance with the geographical conditions a toothed segment of 90° (mountain location) or a pivoting range of 120° (flat terrain without elevations) is advisable. If shadows are to be expected on one side at the location, then the toothed segment can be rotated on the shaft until the radiation is absorbed in a preferred manner, i.e. for longer, by the panel on the free side.

A rocker switch for the motor part with an intermediate gear allows a solar panel which has been pivoted out to be returned to its horizontal rest position in a rapid and energy-saving manner.

A switching magnet which is capable of being switched on for a short time has been found to be successful in actuating the rocker switch. An additional blocking magnet on the rocker switch is recommended for regions subject to strong winds.

An increase in the security of the system and further reduced stressing of the individual solar modules is possible as a result of a divided energy supply.

Although the pivoting movement of the panel requires a high reduction ratio between the motor and the toothed segment, a spur-gear mechanism is recommended on account of the high degree of mechanical efficiency.

In the case of large solar plants with a plurality of similar panels the economic outlay can be enormously reduced if they are coupled to one another. Toothed belts, chains or lever systems are suitable as mechanical driving means. Modern radio-transmission systems (WLAN, Bluetooth), which permit an inexpensive electrical synchronization of the individual drives, are likewise possible.

A position control by means of solenoid-operated switches (reed relays) or Hall-effect sensors simplifies the electronic outlay. They ensured security of the system, in particular the electromagnetic compatibility (EMC) in plants which are erected at locations which are exposed and/or at risk from lightning. It is particularly simple and advantageous to fit the position indicators in the drive. The said position indicators are advantageously installed in or on the gearwheel segment, which carries and turns the support with the solar modules.

The efficient storage of the switching energy for uncoupling the drive and optionally the current supply for the control means is crucially important. After the uncoupling the solar panel is set—by its spring rod and/or torsion rod—in a rest position or starting position and it can receive diffuse light already in the early morning and can control the tilting procedure in the eastern starting position or from the eastern starting position in a western direction. The forces required for this can be adjusted by means of additional springs or by the choice of a suitable switching magnet, so that in no angular position is it possible for a gust of wind to affect the disengagement into the rest position.

It is ideal for the capacitor to be charged by way of a blocking diode since, in this way, the capacitor makes the maximum terminal voltage available into the night.

As a result of using a second magnet which is used to lock the rocker switch, the first magnet (switching magnet) can be made smaller and the rocker can be provided with smaller springs, without the drive of the intermediate gear moving out of the toothed segment. The necessary switching delay of the first magnet with respect to the second magnet occurs as a result of the different inherent mechanical and electrical hystereses, but it can also be set electronically to from 100 to 200 ms.

The use of the plant in conjunction with emergency-power installations increases the security of sensitive infrastructures, without maintenance of the plant as a whole being necessary. It is likewise possible for large solar parks to be produced with the subject of the invention.

Embodiments of the invention are explained below with reference to drawings, in which the same reference numerals are used for the same functional parts. In the drawings

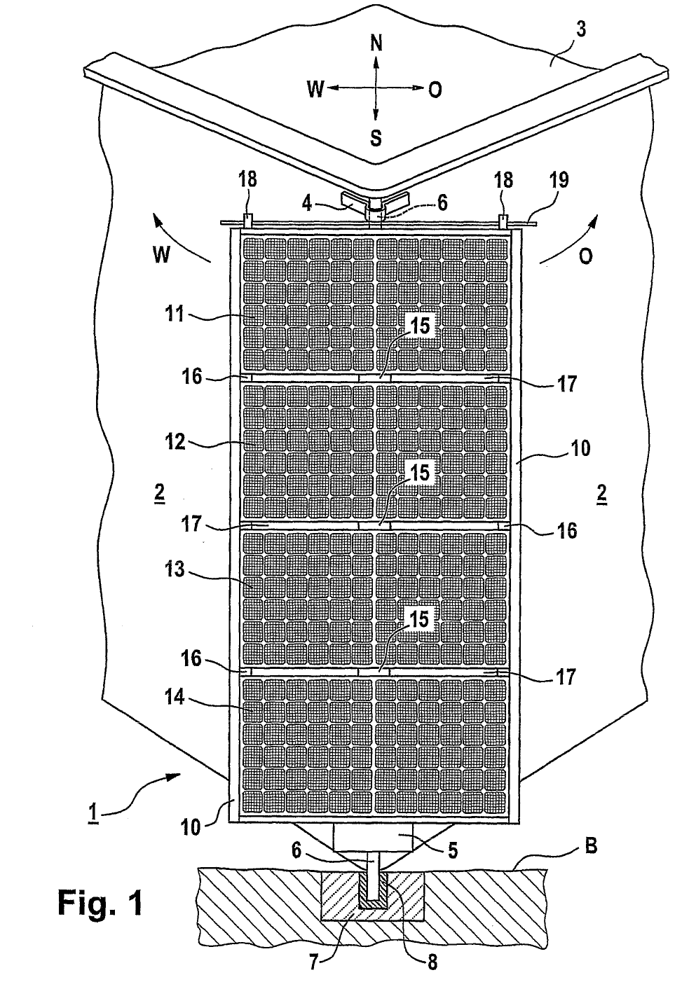

FIG. 1 shows a solar plant with a pivotable panel and a drive unit arranged below and an upper return spring stressed centrally, installed on a corner of a house with a flat roof;

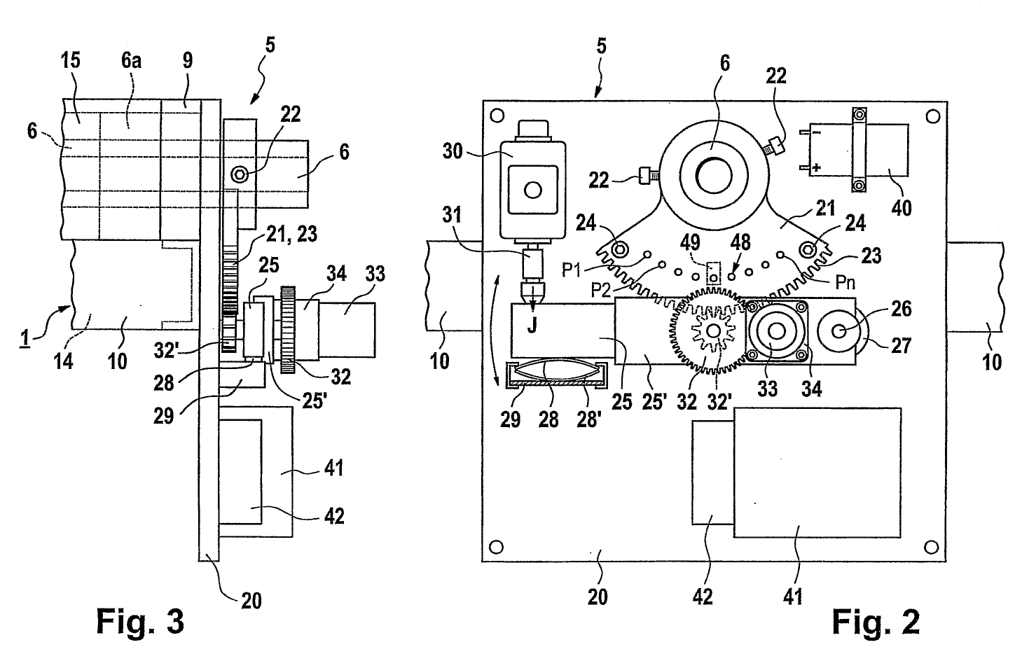

FIG. 2 is a plan view of the structural elements of the drive unit as shown in FIG. 1 with the protective hood removed;

FIG. 3 shows the drive unit as shown in FIG. 2 as viewed from the side;

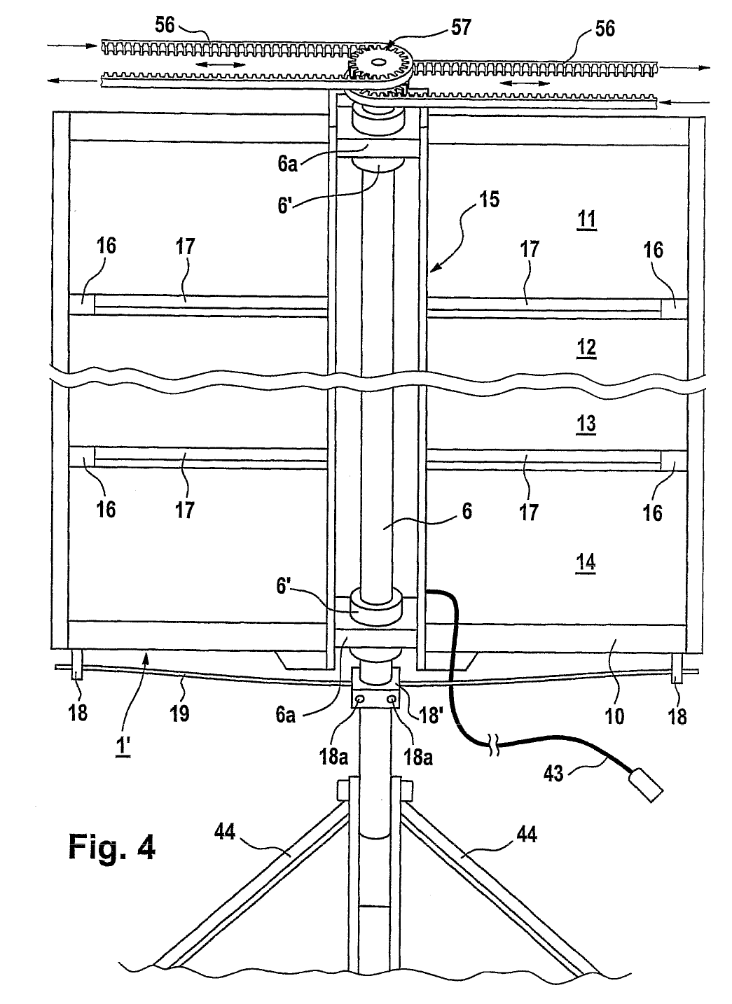

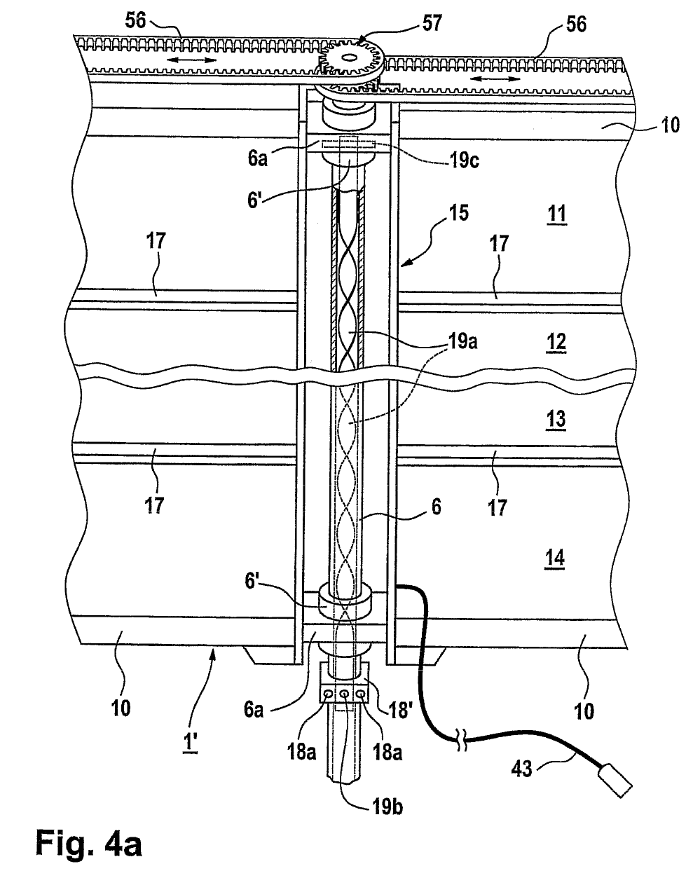

FIG. 4 shows a lower tripod as a mounting for a fixed shaft with a pivotable solar panel, coupled by way of toothed belts to adjacent plants, with a lower return spring;

FIG. 4a is a partial sectional illustration of a variant of a solar panel with an axial torsion rod in a fixed hollow shaft;

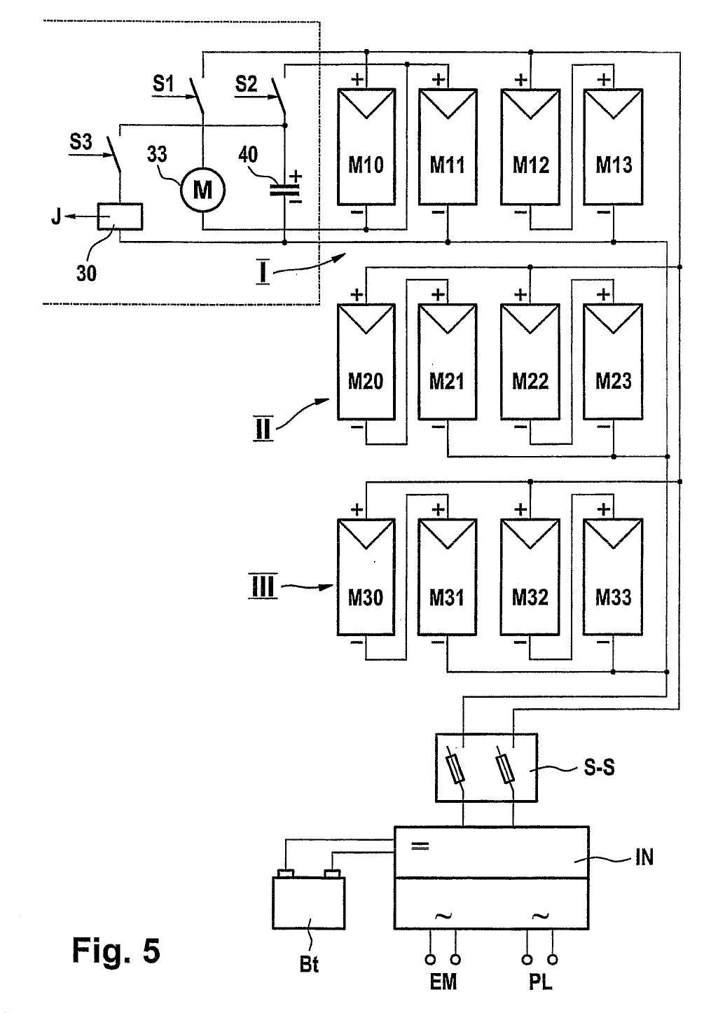

FIG. 5 is a basic illustration of an emergency-power supply with a return feed for the mains with three solar panels and a drive unit;

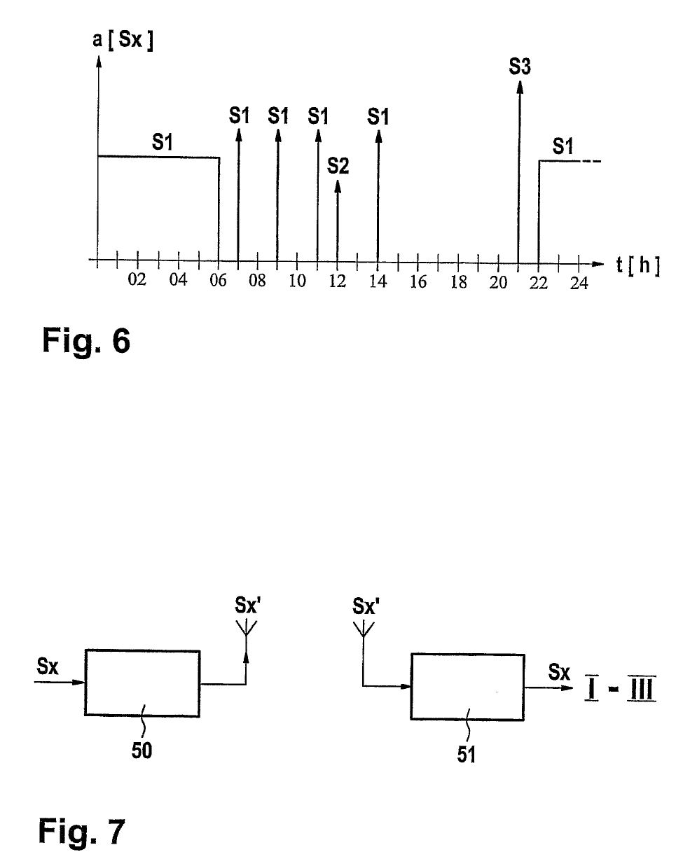

FIG. 6 is a simplified flow chart for the control of the solar panel as shown in FIG. 5, with characteristic control signals Sx;

FIG. 7 shows a wireless transmission line for transmitting the control signals Sx as shown in FIG. 6 to the solar panels;

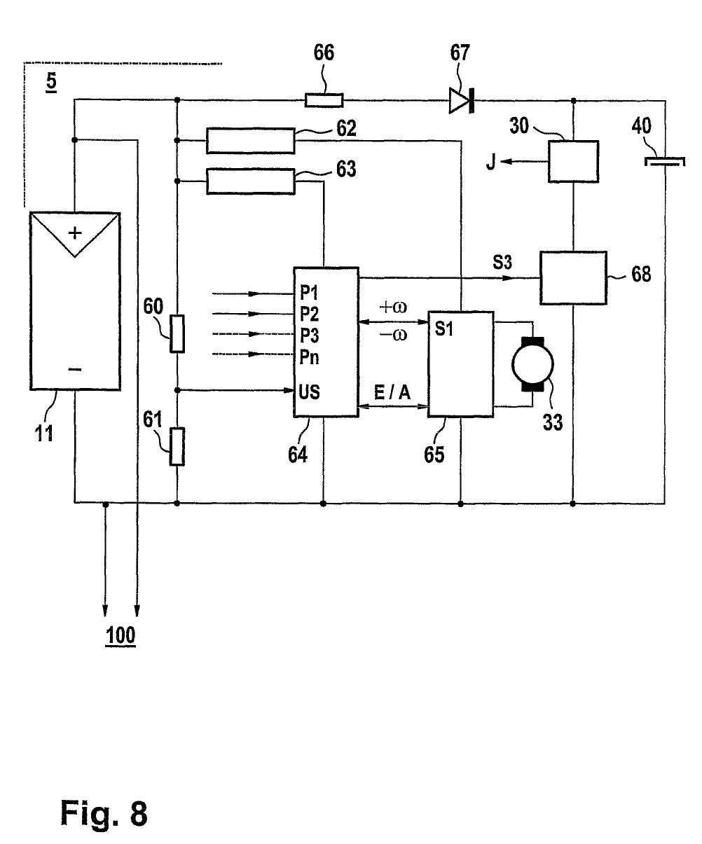

FIG. 8 shows the block diagram of an alternative autonomous control integrated into the drive unit;

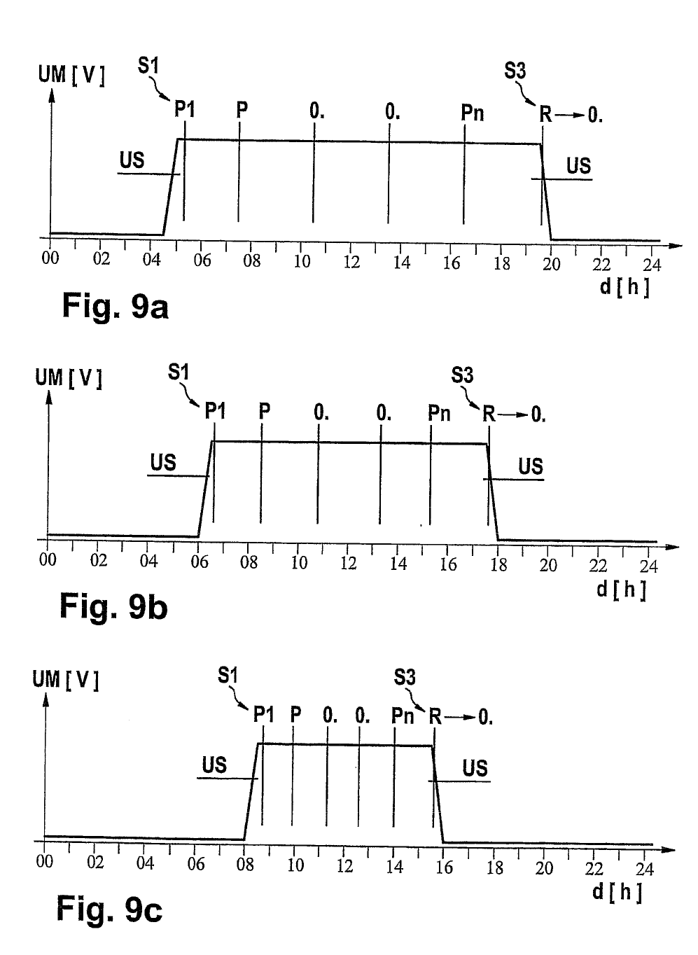

FIGS. 9a to c show the time pattern of the control signals for the control as shown in FIG. 8, in a manner dependent upon the seasons;

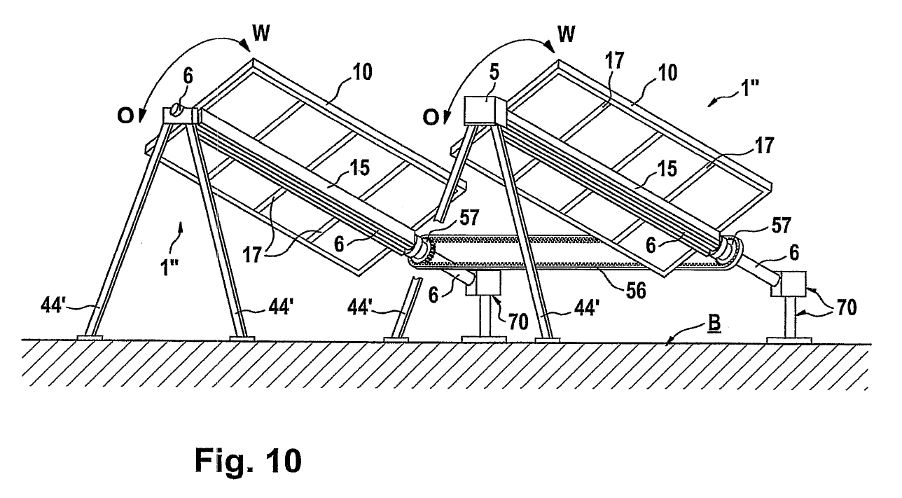

FIG. 10 shows two solar plants coupled mechanically and having a single drive unit;

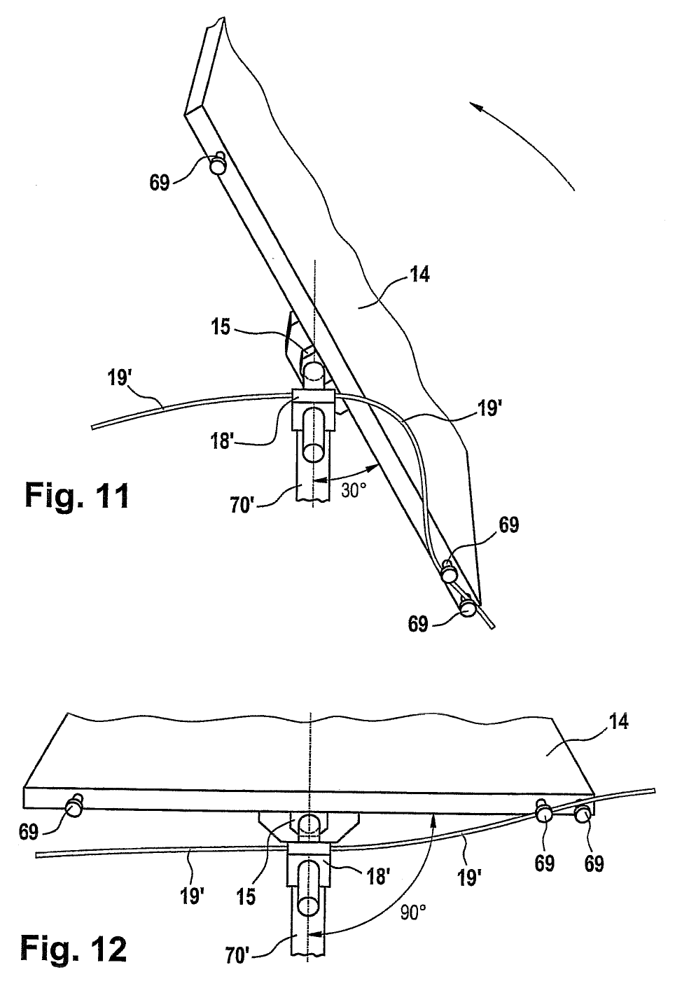

FIG. 11 is a cut-away view of a solar panel with a non-linear returning apparatus by means of a leaf spring in the eastern position (morning);

FIG. 12 shows the solar panel as shown in FIG. 11 in the horizontal position (midday), and

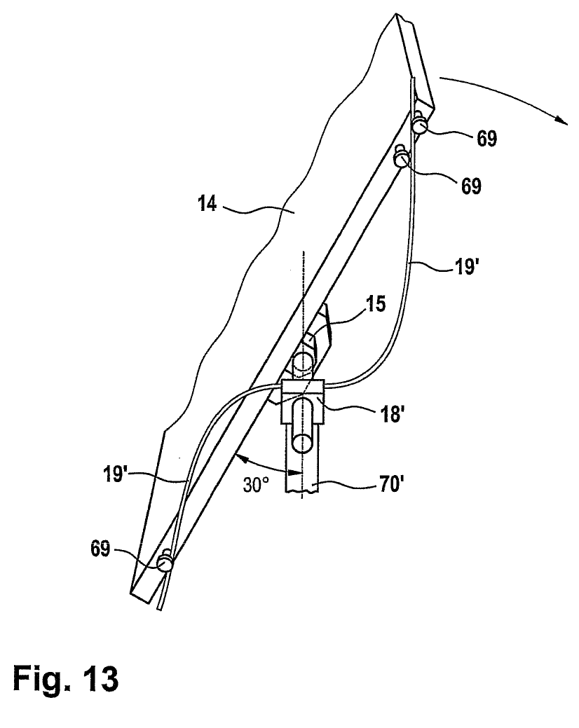

FIG. 13 shows the solar panel as shown in FIG. 11 in the western position (evening).

A solar panel, which is positioned on the corner of two house walls 2 abutting against each other at an angle of 90°, is designated 1 in FIG. 1. The solar panel 1 is formed substantially by four solar modules 11 to 14, which are brought together and fixed in a frame 10 of a U-shaped profile. A flat roof 3 is shaped in a conventional manner; the house is orientated in the north/south direction in its diagonal. A fastening 4 for a stationary shaft 6, which is gripped in a bearing bush 8 and is cemented into a cement casting 7 in the concrete base B, is attached in the upper part of the house corner. An electrical drive 5, which is connected mechanically to a central support 15, is situated below the solar panel 1. Spacer elements 16 are provided between the individual solar modules 11 to 14, so that air gaps 17 which are used for pressure compensation in the case of wind stressing and at the same time prevent the formation of a cohesive covering of ice are formed between the modules. Two slide blocks 18, by which a spring rod 19 fastened to the shaft 6 and used as a return spring for the panel 1 as a whole is guided, project above the solar panel 1. The two parts 16 and 18 consist of a UV-resistant polymer.

As shown in FIG. 2, the electrical drive 5 is set up in the form of an autonomous unit on a base plate 20. The end of the shaft 6, which is constructed in the form of a hollow shaft and which is provided with a gearwheel segment 21, is guided by the base plate 20. The position of the gearwheel segment 21 can be adjusted in its angular setting by fixing screws 22. Position transmitters, which are constructed in the form of magnetic rods 48 and produce position signals P1 to Pn by way of a position sensor 49, are formed in the gearwheel segment 21. Pins 24 project at the ends of the gearwheel segment 21 and are used to limit the path mechanically. In this way, the solar panel 1 can be pivoted by a maximum of 90°, as shown in FIG. 1. A rocker switch 25, 25′ is guided in a rotatable manner at the end on bearing points 26, 27. It acts as a support for a commercially available gear motor 33 with a gear mechanism 34 and intermediate gears 32, 32′, which form a rotational-speed reduction means, the toothed wheel 32′ (pinion) engaging in the set of teeth 23 of the gearwheel segment 21.

The rocker 25 is held on the underside by leaf springs 28, 28′ which are mounted in a spring casing 29. A tappet 31, which is a component part of the armature of a switching magnet 30, rests on the top side of the rocker switch 25. A storage capacitor 40, which is provided in order to actuate the switching magnet 30, is fastened to the right-hand upper side of the base plate 20. An electronic control means 41, by way of the terminal box 42 of which a cabling system (not shown in this case for reasons of clarity) is attached, is arranged in the lower part of the plate 20. The frame 10, to which the base plate 20 is connected in a non-positively locking manner, is visible to the side of the said base plate 20. In FIG. 3 the component parts of FIG. 2 are shown in their depth as viewed from the side. The frame 10, which embraces the solar modules with its U-shaped profile, is again visible in this case. The continuous hollow profile of the shaft 6 in the support 15 as well as the associated carrier 9 (end flange) for the frame 10 are likewise visible. A bearing 6a consists of a polymer with good sliding qualities (Delrin, Trade Mark of the firm DuPont, USA). In the operational state the drive unit present in a servicing position in this case is turned through 180°, i.e. the solar module 14 shown in broken lines is then at the top. The very simple mounting of the shaft 6 in bearings 6a has impressive properties: It is selflubricating and has better lubricating properties in rain and snow than in the dry state, which is the exact opposite of other designs.

It is evident from FIGS. 1 to 3 that, when started, the gear motor 33 turns or can pivot the entire drive system 5 with the support 15, the frame 10 and the modules 11 to 14 about the shaft 6.

A variant of a solar panel 1′ in conjunction with further panels 1′ is illustrated in FIG. 4. The shaft 6 is directed towards the south at an elevation angle of 45°. In contrast to FIGS. 1 to 3, in this case a sliding bushing 6′ is specially provided, which reinforces the shaft 6 and reduces its bending. Two drive wheels 57 for toothed belts 56 are arranged at the upper end of the shaft 6; in this version a drive unit 5 is provided on a shaft 6 of an adjacent plant. As a result, a synchronous running of plants parallel to one another is easily possible with a minimal technical outlay. An attachment cable 43, a standardized so-called solar cable with a plug, is additionally evident in this Figure.

The toothed belts 56 can also be replaced by curved lever systems, which can be advantageous, particularly in regions where there is no risk of icing.

As an alternative, not illustrated here, it is possible for a separate drive 5, which is insulated, i.e. erected without a solar panel, to be provided. Its drive wheel 57 drives the toothed belts 56 with the individual panels 1′, 1

FIG. 4a shows a variant of a return movement with a torsion rod 19a, also referred to as a torsion spring, which is shown simplified in the hollow shaft 6. The said rod 19a is fixed on its lower end face by a screw 19b (in a terminal, not shown), the nut thread for which is provided in a support 18′, it being possible for the latter to be fixed in a displaceable manner on the hollow shaft 6 by screws 18a. The power transmission of the torsion rod 19a to the rotatable panel takes place in the upper frame part 10 and is symbolized by a pin 19c indicated in broken lines.

As shown in FIG. 5, an emergency-power supply with a return feed into the mains uses three tiltable solar panels I to III connected in parallel to one another and with modules M10 to M33. To this end, use is made of a commercially available inverter IN (Sun Profi Emergency, SP 1500 E of the firm Sun Power Solartechnik GmbH, D-61118 Bad Vilbel). This charges batteries Bt (direct-current voltage) and feeds the continuously generated solar power in the form of a one-phase alternating-current voltage into the mains. The associated mains supply is designated PL (power line). The second output EM (emergency) of the inverter IN immediately delivers a voltage if the mains fails. The supply then takes place by the batteries Bt which are recharged during the day. A disconnecting switch S-S with integrated fuses is connected between the solar modules M10 to M33 of the panels I to III and the inverter IN.

For this application, a single electrical drive unit 5 for the pivoting movement of the panels I to III is again sufficient. The drive motor 33 is briefly connected to an upper solar module M10 by a signal S1 by way of a switch, and this leads to a pivoting movement through 7.5 degrees for example. A further module M11 is likewise connected during a brief interval to the storage capacitor 40 by a control signal S2 and the said storage capacitor 40 is charged with the total terminal voltage of for example 45 V. The switching magnet 30 can be actuated at a given time by a control signal S3 with the energy stored in the capacitor 40.

This results in an extremely simple control, at the correct time, of the pivoting movement: The panels I to III are moved through 7.5° in each case by the control signal S1 provided that the sun provides sufficient energy. If this does not happen for a relatively long time or if—normally in the evening—the panels are tilted into their end position towards the west, then the switching magnet 30 is actuated by the control signal S3, and this results in a mechanical pulse J to the rocker switch 25, 25′ and discharges the capacitor 40, see FIG. 2. As a result, the intermediate gear 32′ is lifted from the gearwheel segment 21, so that the return spring 19 (cf. FIG. 1; FIG. 4) turns the panels I to III into their horizontal zero position. After that, the rocker switch 25, 25′, actuated by the leaf spring, 28, 28′ pivots upwards and engages the gearwheel 32′ in the set of teeth 23 again. In this way the individual pivoting angles pre-set by the position transmitters P1 to Pn can be traversed in a manner pre-determined time-wise.

This manner of the time-dependent control permits a complete consideration of the position of the sun, without solar sensors being necessary. This is illustrated by way of example in the characteristic pattern in FIG. 6, where the action a is plotted as a function of time t in the course of a day by the signals S1 to S3.

The following apply in this case:
S1=control signal for the gear motor 33 (pivoting movement)
S2=control signal for charging the electrolyte capacitor 40
S3=control signal for uncoupling the gear mechanism (on the rocker switch 25, 25′), and this leads to a return movement R into the zero position 0.

A possibility of transmitting a signal from a so-called “master” (control unit) to “slaves” is indicated by the transmission path as shown in FIG. 7. A transmitter 50 (WLAN) transforms a control signal Sx as shown in FIG. 6 into a transmission signal Sx′; the latter in turn is transformed into the signal Sx in the receiver 51 and is supplied to the panels I and/or I to III. The coupling between the panels I to III can thus be carried out in a mechanical or electrical manner.

A high-frequency signal transmission can easily be provided by advantageous components and well-known methods of mobile computer technology (for example Bluetooth) even for large solar installations and can be supplied with electricity in a suitable manner, without perceptible damage to the solar energy balance.

In a preferred embodiment, FIG. 8, a drive unit 5 receives its energy from a single solar module 11. The gear motor 33 is supplied by way of a voltage regulator 62 and a bridge circuit 65. A microprocessor 64 is supplied by way of a voltage regulator 63. The threshold-value input US of the microprocessor 64 is connected to the pick-up of a resistance bridge 60, 61 connected to the module 11 and it switches the latter into its functional state when there is a sufficiently high input voltage, for example 38 V.

This may be seen from the diagrams in FIGS. 9a to 9c, in which FIG. 9a shows the terminal voltage UM (in volts) at the module in a typical summer phase, FIG. 9b shows the terminal voltage UM in spring or autumn and FIG. 9c shows a typical winter phase. If FIG. 2 is viewed in conjunction with FIGS. 9a to 9c, then it is evident that the magnetic rods 48 are formed at equal distances on a pitch circle of the toothed segment 21. Together with the reed switch 49 they form position transmitters P1 to Pn. The time intervals between the individual steps of P1 to Pn are divided uniformly by the presumed length of the day calculated in the microprocessor 64 (FIG. 8). Depending upon the length of the day, the intervals are shorter (for example FIG. 9c) or longer (FIG. 9a). In this way, the program stored in the microprocessor 64 controls the panel 1 in an adaptive manner (“adaptive control”).

As soon as the threshold-value voltage US has been achieved, a counter contained in the processor 64 (FIG. 8) begins with its counting function and stops when the voltage US fails to be reached. In this way, it is possible for a daily pattern with its effective duration of sunshine to be stored; this is repeated daily and an average, which is used for the sequential division of the control signals into the individual steps P1, P2 to Pn, is formed from the measured values of the previous 8 days. A comparison of the diagram of summer, FIG. 9a, with winter, FIG. 9c, shows how the step length changes. In this way an automatic adaptation of the system to the time of year is carried out, i.e. when the duration of sunshine is shorter an improved adaptation to the direction of radiation takes place.

The typical horizontal settings of the panel 1 or 1′ respectively are referred to as zero positions 0; cf. FIGS. 9a to 9c. In this case the signal S3 likewise causes the pivoting out of the gearwheel 32′, as described above, and, as a result, the return R of the panel into the zero position 0. After that, the gearwheel 32′ engages again; even in the case of a diffuse dawn occurring, when the threshold-value voltage US has been achieved again the plant is now ready to emit control signals S1 in order to first to move to the position P1 and then, in a time sequence, the further positions P2 to Pn as shown in FIGS. 9a to 9c.

The feedback of the signals of the position transmitters P1 to Pn is indicated on the microprocessor 64, FIG. 8; as a result the current supply to the bridge circuit 65 and to the motor 33 is interrupted, this being indicated as E and as A respectively in FIG. 8. The reversal of the direction of rotation −ω/+ω likewise takes place on the said component 65 constructed in the form of a double bridge.

Whereas FIG. 5 relates to electromagnetic switches (relays) S-S with corresponding galvanic separation, in accordance with FIG. 8 semiconductor elements are used.

The charging of the electrolyte capacitor 40, FIG. 8, is carried out by way of a serial resistor 66 and a blocking diode 67, i.e. possible leakage currents in the capacitor 40 are automatically compensated. The control signal S3 is supplied from the microprocessor 64 to the input of an electronic switch 68 (CMOS FET) which actuates the switching magnet 30.

A preferred embodiment of a plant consisting of two panels 1″, which both have an angle of elevation of 30°, is illustrated in FIG. 10. The shafts 6 of the two panels 1″ are in turn fixed in supports 44′ and, in addition, in a low stand 70. The entire unit is set up on a flat concrete roof of a building. A single drive 5 controls the two panels 1″ autonomously. The coupling by way of a toothed belt 56 is illustrated in a simplified manner, it extends in fact in a “chain case” and contains clamping members known per se in order to compensate expansion caused by temperature.

In this variant a return by means of a spring rod 19 has been omitted, cf. FIG. 1 and FIG. 4. This is carried out in this case by way of the drive 5 and the toothed belts 56. Blocking the toothed belts during the horizontal zero setting, for example on the tensioning members thereof, likewise results in a desired spring action by way of the resilient belts 56.

Spring rods 19′ of rectangular cross-section (leaf spring) as shown in FIGS. 11 to 13 have proved successful in individually controlled plants.

It is clear from FIG. 11 how the panel, in its position tilted towards the east (O), tensions the leaf spring 19′ on the front face against the module 14 and restores the latter to the rotational movement in the direction of the arrow towards the west even in the case of a very low torque still present on the drive in the morning. The spring force required can easily be set in an experimental manner by turning and clamping—by means of screws not shown in this case—on the adjustable support 18′. The leaf spring is guided on metallic rolls 69.

The shape and position of the leaf spring at midday may be seen in FIG. 12; likewise in the evening in FIG. 13.

In contrast to the previous embodiment, the entire pivoting angle amounts to 120°, which is illustrated in FIGS. 11 and 13 by the supplementary angles of 30° with respect to the stand 70′. In plants with highly efficient inverted rectifiers with MPP (maximum power point) regulation it is known that energy is still converted in the final phase of twilight, so that the return of the panel advantageously takes place only in complete darkness. For this purpose it is recommended that a further charging capacitor for providing the current supply of the control means should be used, this being analogous to the electrolyte capacitor 40. This buffering also ensures that the control means is started at the correct time, even if the inverted rectifier “draws off” the minimum energy present at dawn and the supply voltage is not sufficient for the current supply.

Depending upon the nature of the solar modules, a single plant of this type easily allows a maximum output Pp of 1600 W to be achieved and can be used for ensuring the supply of even large servers and/or communication centres, optionally also in long-term emergency-power operation, in a reliable manner. Even under unsettled cloudy conditions the buffer batteries required for this are charged in the evenings; on such days the gain in energy amounts to up to 36% as compared with stationary plants.

The possibilities of combination and adaptation of the subject of the invention are almost infinite, but the autonomous arrangement—insignificant in terms of power—of the control of optimized solar plants at the correct time permits individual adaptations to specific applications and to the technical means used in this case.

The plant can also of course be adapted in elevation to the winter/summer position of the sun. With a corresponding technical outlay the subject of the invention could also be constructed in the form of a biaxial tracking, but this seems to be inadvisable on economic grounds at present. The simple structural arrangement allows the design of a plant according to the invention almost everywhere and thus allows existing plants to be retrofitted in numerous cases whilst retaining the electrical infrastructure (inverted rectifiers, mains supply etc.). Measurements have shown that under very unsettled cloudy conditions a plant tracking on one axis can deliver a surplus of up to 36% as compared with stationary plants with the same elevation.

The adjustment steps of the panel illustrated in the embodiments are limited in their number only by the design of the position transmitters P1 to Pn (interferences). On economic grounds more than 16 steps are scarcely feasible.

The subject of the invention represents a contribution to an assured and environmentally harmless energy supply under economic conditions.

1. A solar plant with at least one solar panel comprising at least one photovoltaic solar module which solar panel is pivotable about a stationary shaft forming an axis of rotation by an electrical drive in an intermittent and program-controlled manner and is capable of being directed for the maximum solar radiation in the course of the day, wherein the pivoting movement of the electrical drive of the control means is supplied by one of the solar modules intended for energy generation, characterized in that an end face of the shaft (6, 6′) carries a fixed gearwheel (21) about which a drive (5) connected in a non-positively locking manner to the support (15) for the at least one solar modules (11 to 14) is guided in a sectoral manner dependent upon the time of day for directing the at least one solar module towards the sun.

2. A solar plant according to claim 1 with a plurality of solar modules (11 to 14), characterized in that, as viewed in an axial direction, the modules (11 to 14) are arranged at a distance from one another at end faces by spacer elements (16) and air gaps (17), and the spacer elements (16) consist of an elastomer and have a width of from 15 to 50 mm.

3. A solar plant according to claim 1, characterized in that the solar modules (11 to 14) extend above a U-shaped support (15) which contains bearings (6a) for the shaft (6, 6′) forming the axis of rotation.

4. A solar plant according to claim 3, characterized in that the solar modules (11 to 14) are held laterally and centred in a U-shaped frame.

5. A solar plant according to claim 1, characterized in that at least one spring rod (19, 19′), having ends that engage on a frame (10) which grips the solar modules (11 to 14), is fixed to the shaft (6).

6. A solar plant according to claim 5, characterized in that the spring rod (19) is a leaf spring mounted centrally on the shaft (6) in a displaceable support (18″), the frame having a first east-extending end face and a second west-extending end face, the spring rod engaging two rollers (69) at one of the frame end faces and engaging a single roller (69) at the other of the frame end faces.

7. A solar plant according to claim 6, characterized in that the shaft (6) is a hollow shaft, and a sliding bushing (6′) mounted in a non-positively locking manner is provided on the hollow shaft at least in a lower bearing (6a).

8. A solar plant according to claim 1, characterized in that the electrical drive (5) is flange-mounted on an end face of the solar panel (1, 1′), the gearwheel (21) is constructed in the form of a gearwheel segment on the stationary shaft (6), one gearwheel (32′) of a gear mechanism (32′; 32, 34) engages the gearwheel segment (21), and the gear motor (33) pivots the drive (5) step-wise about the shaft (6) by a central angle of at least 90° in advance (+ω) and in return (−ω).

9. A solar plant according to claim 8, characterized in that the gear mechanism (32′; 32, 34) and the gear motor (33) are mounted on a rocker switch (25, 25′) for travel out of engagement with the gearwheel segment (21).

10. A solar plant according to claim 9, characterized in that the rocker switch (25, 25′) is biased by springs (28, 28′) in the direction of the gearwheel segment (21), and a switching magnet (30) is provided to move the rocker switch (25, 25′) and thus the driving gearwheel (32′) out of engagement with the gearwheel segment (21).

11. A solar plant according to claim 10, characterized in that the rocker switch includes a locking magnet.

12. A solar plant according to claim 10, characterized in that at least two solar modules (11, 12) are provided, wherein one module (11) supplies the gear motor (33) of the drive (5) in an intermittent manner and the other module (12) provides a current supply for at least one of a control means and at least one switch member for uncoupling the gear mechanism (32′; 32, 34) from the stationary shaft (6).

13. A solar plant according to claim 8, characterized in that the gear mechanism (32′; 32, 34) is a spur-gear mechanism.

14. A solar plant according to claim 1, characterized in that a plurality of solar panels are arranged adjacent with a central electrical drive (5), which synchronizes the pivoting movements of the solar panels (1, 1′) with one another mechanically.

15. A method of operating a solar plant with at least one photovoltaic solar module which is pivotable about a stationary shaft by an electrical drive in an intermittent and program-controlled manner and is capable of being directed for the receipt of maximum solar radiation in the course of the day, wherein the pivoting movement of the electrical drive of the control means is supplied by a solar module intended for energy generation, characterized in that an electrical threshold value (US), which corresponds to dawn and twilight, is detected on a solar module (11 to 14) by way of a microprocessor (64), a duration value of daylight is determined therefrom by a counting process, this value is stored in the microprocessor (64), an average value is formed from the stored values of several days, the average value is divided into equal individual steps (P1 to Pn), the resulting intervals (P1, P2 to Pn) actuate a gear motor (33) with a signal (S1) in such a way that individual steps of the pivoting movement of the panel (1) from east (O) to west (W) are created and divided at least approximately uniformly over the course of the day, and the panel (1) is turned back towards the east (O) during or after the twilight.

16. A method according to claim 15, characterized in that the actuated gear motor (33) is temporarily switched off by position transmitters (48) and at least one position sensor (49).

17. A method according to claim 15, characterized in that a capacitor (40) is charged by a solar module (11 to 14) in the course of the day, and that, during the twilight or at night and after the threshold-value voltage (US) fails to be reached a control signal (S2) is transmitted by the microprocessor (64) to a power switch (68), and the power switch (68) switches the charge stored in the capacitor (40) to a solenoid of at least one switching magnet (30) which moves a rocker switch (25, 25′) and a connected gear mechanism (32; 32′, 34) from a gearwheel segment (21) for a short time, and, as a result, a mechanical pre-stressing of pivoting means for the panel (1) is released, as a result of which it is moved back into an east position (O).

18. A method according to claim 17, characterized in that the capacitor (40) is constantly acted upon during the day with a voltage of a solar module (11), and a blocking diode (67), which continuously compensates for a leakage current of the capacitor (40), is connected upstream of the capacitor (40).

19. A method according to claim 17, characterized in that the capacitor (40) is discharged by way of a second magnet which engages in the rocker switch (25, 25′) and is activated from 100 to 300 ms before the first switching magnet (30), and in this case the rocker switch (25, 25′) is unlocked.

20. (canceled)
